(19) United States
(12) Patent Application Publication
(10) Pub. No.: US 2025/0111108 A1
(43) Pub. Date: Apr. 3, 2025

(54) MACHINE LEARNING ESTIMATION OF RESERVOIR FLUID PROPERTIES

(71) Applicant: Schlumberger Technology Corporation, Sugar Land, TX (US)

(72) Inventors: Ivan Fornasier, Paris (FR); Maneesh Pisharat, Buchareat (RO); Ana Escobar, Bagneux (FR); Pawel Presnal, Clamart (FR)

(21) Appl. No.: 18/593,158

(22) Filed: Mar. 1, 2024

(30) Foreign Application Priority Data
Sep. 28, 2023 (EP) 23306629.9

(51) Int. Cl. G06F 30/27

(52) U.S. Cl. CPC G06F 30/27

(57) ABSTRACT

A method for estimating reservoir fluid properties includes classifying the reservoir fluid as normal or abnormal from a measured gas composition and a classified fluid type with a trained machine learning model, predicting a heavy hydrocarbon fraction of the reservoir fluid when the reservoir fluid is classified as normal from the measured composition and the classified fluid type with a another trained machine learning, and predicting a heavy hydrocarbon fraction of the reservoir fluid when the reservoir fluid is classified as abnormal from the measured composition and the classified fluid type with a still another trained machine learning model.

### CROSS REFERENCE TO RELATED APPLICATIONS

This application claims priority to and the benefit of European Application No. 23306629.9, filed on Sep. 28, 2023, the entirety of which is incorporated herein by reference.

### BACKGROUND

When drilling a well for the production of hydrocarbons, drilling fluid is often circulated through the well for a number of purposes. For example, drilling fluid is commonly intended to provide pressure to the subterranean formation, cool and lubricate the drill bit, flush cuttings away from the drill bit and carry them to the surface, and provide hydraulic power to various downhole tools. Drilling fluids also commonly carry formation fluids and dissolved formation gasses to the surface. Such gasses may be liberated by the drill bit as it cuts the formation.

The liberated gases are commonly evaluated at the surface while drilling (e.g., via gas chromatography) to measure the amounts of various alkane gasses such as methane (C1), ethane (C2), propane (C3), butane (C4), pentane (C5) in the gas stream. Such measurements may provide valuable information to a mud logger and may provide information about the maturity and nature of hydrocarbons in the reservoir, compartmentalization of intervals in the reservoir being drilled, and oil quality, as well as information regarding production zones, lithology changes, history of reservoir accumulation, seal effectiveness, and environmental impact of the drilling operation.

While such gas measurements may provide valuable insight about the contents of the reservoir, there is room for further improvement. For example, there is a need to further evaluate the gas composition measurements to infer (or estimate) additional reservoir fluid properties such as the fluid type, the gas-oil-ratio, and the heavy hydrocarbon fraction (e.g., C6, C7, C8, and so on) fraction.

### BRIEF DESCRIPTION OF THE DRAWINGS

For a more complete understanding of the disclosed subject matter, and advantages thereof, reference is now made to the following descriptions taken in conjunction with the accompanying drawings, in which:

FIG. 1 depicts an example drilling rig including a disclosed system for making mud logging measurements.

FIG. 2 depicts another embodiment of a surface system for making mud logging measurements.

FIG. 3 depicts a flow chart one example method for estimating reservoir fluid properties from gas composition measurements.

FIG. 4 depicts a flow chart another example method for estimating reservoir fluid properties from gas composition measurements.

### DETAILED DESCRIPTION

Embodiments of this disclosure include methods and systems for estimating reservoir fluid properties from gas composition measurements. In one example embodiment, a disclosed method includes obtaining a measured composition of a gas sample obtained during a mud logging operation, the measured composition including selected alkane gases; classifying the reservoir fluid as normal or abnormal from the measured composition and the classified fluid type with a trained machine learning model; predicting a heavy hydrocarbon fraction of the reservoir fluid when the reservoir fluid is classified as normal from the measured composition and the classified fluid type with a another trained machine learning; and predicting a heavy hydrocarbon fraction of the reservoir fluid when the reservoir fluid is classified as abnormal from the measured composition and the classified fluid type with a still another trained machine learning model. The method may optionally further include predicting a gas oil ratio of the reservoir fluid from the measured composition, the classified fluid type, and the predicted heavy hydrocarbon fraction with a yet another trained machine learning model.

Disclosed embodiments may advantageously enable an accurate prediction of reservoir fluid properties, including the reservoir fluid type, the C6+ fraction in the gas oil ratio of the fluid. Moreover, the disclosed embodiments advantageously account for the presence of irregular or abnormal fluids, for example, those subject to biodegradation, and may advantageously provide a robust and precise prediction of the gas oil ratio of the reservoir.

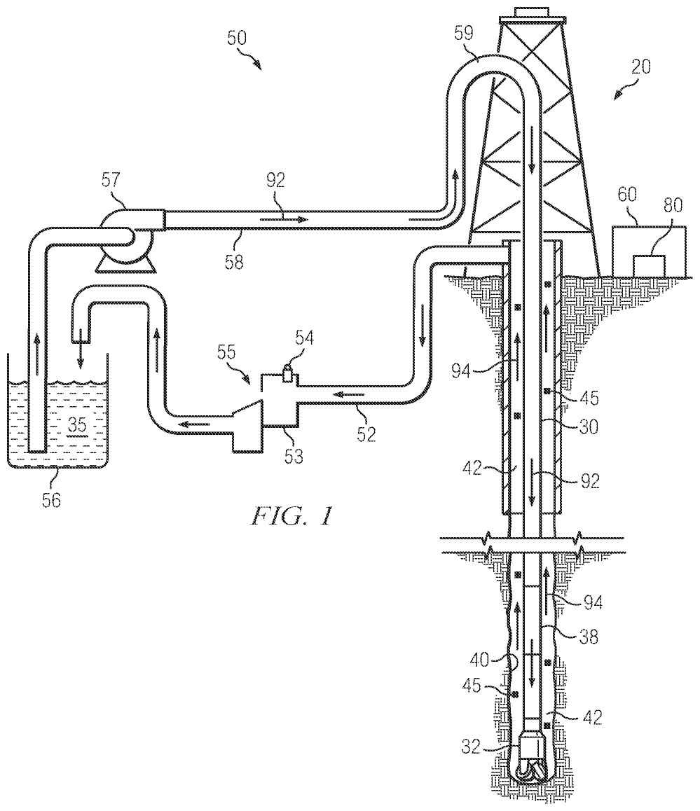

FIG. 1 depicts an example drilling rig 20 including a system 80 for making mud logging measurements (e.g., making gas composition measurements and estimating reservoir fluid properties from the measurements). The drilling rig 20 may be positioned over a subterranean formation or reservoir (not shown). The rig 20 may include, for example, a derrick and a hoisting apparatus (also not shown) for raising and lowering a drill string 30, which, as shown, extends into wellbore 40 and includes, for example, a drill bit 32 and one or more downhole measurement tools 38 (e.g., a logging while drilling tool or a measurement while drilling tool) in a bottom hole assembly (BHA) above the bit 32. Suitable drilling systems, for example, including drilling, steering, logging, and other downhole tools are well known in the industry.

Drilling rig 20 further includes a surface system 50 for controlling the flow of drilling fluid used on the rig (e.g., used in drilling the wellbore 40). In the example rig depicted, drilling fluid 35 may be pumped downhole (as depicted at 92), for example, via a conventional mud pump 57. The drilling fluid 35 may be pumped, for example, through a standpipe 58 and mud hose 59 in route to the drill string 30. The drilling fluid 35 typically emerges from the drill string 30 at or near the drill bit 32 and creates an upward flow 94 of mud through the wellbore annulus 42 (the annular space between the drill string and the wellbore wall). The drilling fluid 35 then flows through a return conduit 52 to a mud pit system 56 where it may be recirculated. It will be appreciated that the terms drilling fluid and mud are used synonymously herein.

The circulating drilling fluid 35 is intended to perform many functions during a drilling operation, one of which is to carrying drill cuttings 45 to the surface (in upward flow 94). The drill cuttings 45 are commonly removed from the returning mud via a shale shaker 55 (or other similar solids control equipment) in the return conduit (e.g., immediately upstream of the mud pits 56). Gases that are released or generated during drilling may also be carried to the surface in the circulating drilling fluid. These gasses, which may be dissolved in the mud or in the form of bubbles, are commonly removed from the drilling fluid, for example, via one or more degassers 54 located in or near a header tank 53 that is immediately upstream of the shale shaker 55 in the example depiction. The drill cuttings 45 and the extracted gases are commonly examined at the surface to assist the drilling operation and to evaluate the formation layers and the reservoir though which the wellbore is drilled.

As is known to those of ordinary skill in the art, formation gas may be released into the wellbore 40 via the drilling process (e.g., crushing the formation rock by the mechanical action of the drill bit) and may also migrate into the wellbore 40, for example, via fractures in the formation rock. The drilling process may also generate gases, for example, via drill bit metamorphism (DBM). Once in the wellbore, the gases may be transported to the surface via the drilling fluid (in the upwardly flowing fluid 94). The gases may be in solution (dissolved) in the drilling fluid and/or in the form of bubbles and may be sampled in the surface system, for example, via the one or more drilling fluid degassers 54 and/or a head space gas probe. The disclosed embodiments are not necessarily limited in regards to how the gas is sampled.

With further reference to FIG. 1, drilling rig 20 may further include a testing facility 60 (e.g., a mud logging system or a laboratory trailer including one or more instruments suitable for making various measurements of sampled gases in the drilling fluid). In the depicted embodiment, the testing facility 60 has instrumentation (such as a gas chromatography apparatus) and is configured to measure the formation gas composition. The testing facility 60 may, of course, include numerous other testing instruments known to those of ordinary skill. The facility may further include a system 80 configured for estimating reservoir fluid properties from gas composition measurements. The system 80 may include the instrumentation or may be configured to receive the gas composition measurements from the instrumentation (e.g., the gas chromatography apparatus). The system 80 may further include computer hardware and software configured to estimate the reservoir fluid properties from the gas composition measurements. The hardware may include one or more processors (e.g., microprocessors) which may be connected to one or more data storage devices (e.g., hard drives or solid state memory) and user interfaces. The system 80 may be further configured to receive a trained machine learning model. It will be further understood that the disclosed embodiments may include processor executable instructions stored in the data storage device. The executable instructions may be configured, for example, to execute methods 100 and 150 to predict reservoir fluid properties from received gas measurements as described in more detail below. The disclosed embodiments are, of course, not limited to the use of or the configuration of any particular computer hardware and/or software.

It will of course be appreciated that while FIG. 1 depicts a land rig 20, that the disclosed embodiments are equally well suited for land rigs or offshore rigs. As is known to those of ordinary skill, offshore rigs commonly include a platform deployed atop a riser that extends from the sea floor to the surface. The drill string extends downward from the platform, through the riser, and into the wellbore through a blowout preventer (BOP) located on the sea floor. The disclosed embodiments are expressly not limited in these regards.

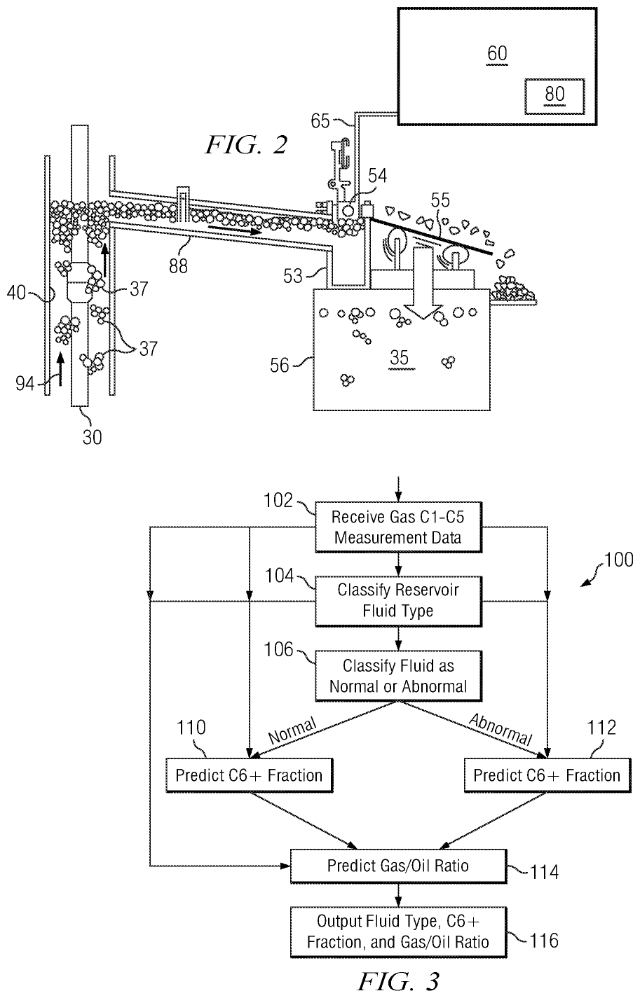

FIG. 2 depicts another view of a portion of surface system 50. As described above, the return conduit 52 is configured to carry drilling fluid 35 (sometimes including gas bubbles 37) from wellbore 40 to mud pit 56. The example system 50 depicted includes at least one degasser 54 deployed, for example, in or near a header tank 53 that is immediately upstream of the shale shaker 55 and mud pit 56. In this example configuration, the degasser 54 is configured to remove gases from the drilling fluid that emerges from the wellbore 40 (referred to in the industry as gas-out). A small volume of the drilling fluid may be circulated through the degassers 54 where it is agitated and optionally heated to remove alkane and other gases from the volumes of fluid.

It will be appreciated that the degasser 54 may include substantially any suitable type of degasser, for example, including vacuum degassers, centrifugal degassers, and impeller degassers. The degasser may further be configured to heat the drilling fluid 35 to promote enhanced degassing of the fluid. The disclosed embodiments are not limited in regard to the type of degasser employed.

As further depicted in FIG. 2, in example embodiments, the degassers 54 may be piped directly to the mud logging unit or rig laboratory 60 (e.g. as depicted at 65), for example, to automatically transport the sampled gases to a gas chromatography apparatus for compositional testing. Moreover, while not depicted, the system 50 may include one or more pumps (e.g., suction or pressure boosting pumps) configured to pump the sampled gas from the degasser 54 to the laboratory 60. The disclosed embodiments are, of course, not limited in regards to any sampling, pumping, or gas transport configurations.

As noted above, the mud logging system or laboratory may include a gas analyzer or measurement device such as a gas chromatography (GC) measurement device. Common GC analyzers include a gas sample injection port configured to feed a gas sample into a column assembly including at least a main GC column. The gas sample is generally mixed with a carrier gas such as nitrogen, argon, helium, or air and transported through the column assembly. An optional precut column may remove heavier hydrocarbon compounds such as those compounds having a number of carbon atoms above a threshold (e.g., C6, C8, or C10 and above). The main column generally includes a stationary phase and is intended to separate the various gas compounds in the gas sample such that they arrive at a detector at distinct elution times, for example, such that C1 arrives before C2, which arrives before C3, and so on. The detector may include substantially any suitable GC detector, such as an FID detector, a TC detector, or a mass spectrometer.

The gas measurement device may be configured to quantify the amounts of light alkanes and optionally other gases (e.g., alkenes and alcohols) in the gas sample. In suitable embodiments, at least the following light alkane gases may be quantified: methane (C1), ethane (C2), propane (C3), n-butane (nC4), iso-butane (iC4), n-pentane (nC5), and iso-pentane (iC5). However, it will be understood that the disclosed embodiments are not limited in this regard as in other embodiments, the gas measurement device may quantify other compounds as aromatics (e.g., benzene and toluene), cyclics (e.g., cyclopentane, methylcyclohexane), and inorganics (e.g., hydrogen, helium, carbon monoxide, and carbon dioxide).

In one example embodiment the gas measurement system (including the degasser in the measurement device) may include an advanced gas service, such as FlairFlex service (available from SLB), configured for monitoring the composition of the reservoir (particularly C1 through C5). The Flairflex service provides lab quality gas composition measurements of the reservoir fluids during drilling and may be used for hydrocarbon and fluid contacts identification and inter- and intra-well fluid facies mapping. Gas composition measurements from Flairflex may guide optimum sampling and downhole fluid analysis, as well as early detection of reservoir complexities (tight, thin layered, etc.). While the following embodiments are described with respect to receiving Flairflex gas composition measurements, it will be understood that these are merely examples and that the disclosed embodiments are not limited to the use of any particular gas chain configuration. In general, the disclosed embodiments only require the measurement of C1 though C5 compounds. It will also be appreciated that these measurements may be obtained using substantially any suitable gas measurement apparatus, for example, including GC-FID, GC-TCD, GC-MS, MS, adsorption spectroscopy (e.g., IR, MID), and/or Raman spectroscopy.

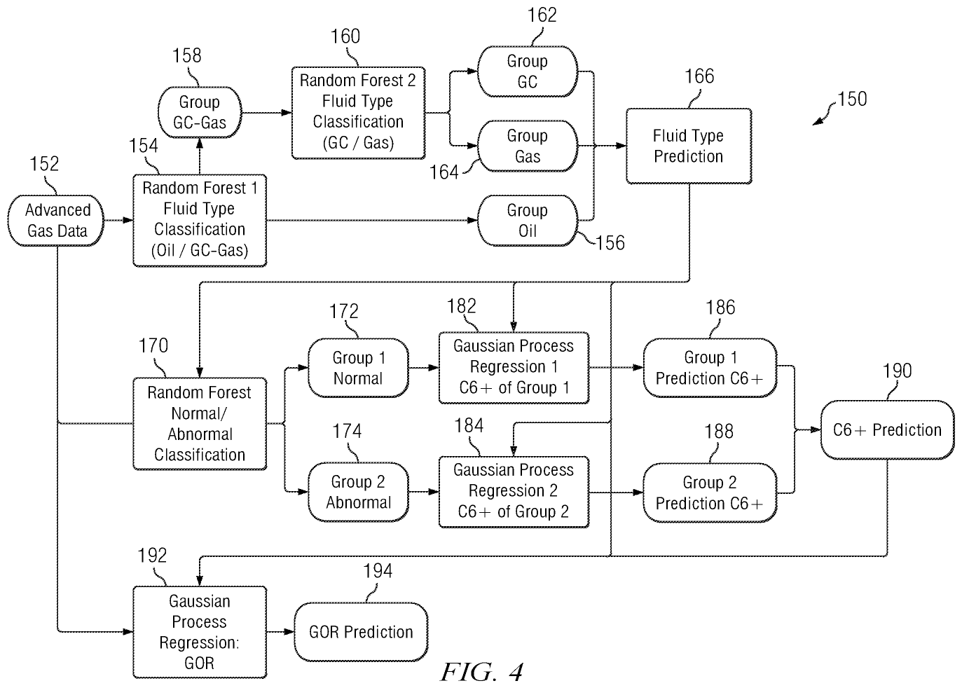

Turning now to FIGS. 3 and 4, flow charts of example methods 100 and 150 for estimating reservoir fluid properties from mud logging gas composition measurements are depicted. Methods 100 and 150 may be conducted in real time during a mud logging operation, for example, while drilling a subterranean wellbore. In FIG. 3, the gas measurements are received at 102. The gas measurements may include C1, C2, C3, C4, and C5 measurements, for example, C1, C2, C3, iC4, nC4, iC5, and nC5 measurements. The gas measurements may be made, for example, using the FlairFlex service as described above. In example embodiments, the gas measurements include circulating drilling fluid in a wellbore while drilling, degassing a portion of the drilling fluid to obtain a gas sample, and making GC measurements to obtain a composition of the gas sample (e.g., a C1 through C5 composition).

The gas measurements received that 102 may be evaluated using a first machine learning fluid classification model at 104 to estimate a reservoir fluid type. For example, the reservoir fluid type may be classified as gas, gas condensate, or oil (e.g., black oil). The gas measurements received at 102 and the estimated fluid type classified at 104 may be evaluated using a second machine learning model at 106 to classify the fluid as normal or abnormal. The gas measurements received at 102 and the estimated fluid type classified at 104 may be further evaluated at 110 or 112 using a third or fourth machine learning model to predict a heavy hydrocarbon fraction (referred to herein as a C6+ fraction) of the reservoir fluid. The third machine learning model may be used at 110 when the fluid is classified as normal at 106 and the fourth machine learning model may be used at 112 when the fluid is classified as abnormal at 106. The gas measurements received at 102, the estimated fluid type classified at 104, and the C6+ fraction predicted at 110 or 112 may be further evaluated at 114 using a fifth machine learning model to predict the gas oil ratio (GOR) of the reservoir fluid. The estimated fluid type classified at 104, the C6+ fraction predicted at 110 or 112, and the GOR predicted at 114 may then be output at 116, for example, via a mud gas log. The process may then be repeated substantially any number of times with successive gas composition measurements.

While the disclosure refers to the heavy hydrocarbon fraction as a C6+ fraction, it will be understood that the disclosed embodiments are not so limited. Gas composition measurements commonly include C1, C2, C3, C4, and C5 measurements (the light hydrocarbon or light alkane gases). Hence the heavy hydrocarbon fraction may be referred to as the C6+ fraction. However, in alternative embodiments the heavy hydrocarbon fraction may refer to other hydrocarbons, for example, C8+ or C10+ depending on the nature of the gas composition measurements and the nature of the reservoir fluid.

With continued reference to FIG. 3, the first machine learning model used for the fluid type classification at 102 may include a statistical learning model that categorizes the hydrocarbon fluid as black oil, gas condensate, or dry gas. Advanced statistical learning tools may be used to build a classification model to accurately identify the fluid type with a given set of input parameters, such as molar gas composition (C1-C5 mol %). Statistical learning refers to a wide range of tools for exploring and understanding data through statistical models. The classification model may be used for estimating/predicting an output based on one or more inputs and is trained with historical reservoir fluid data.

A database containing fluid properties of reservoir fluids may be used to build, train, and validate the statistical models. In advantageous embodiments, the database may contain several thousand samples distributed into the three type of fluids (oil, gas condensate, and gas). Exploratory data analysis techniques may be used to identify a set of relevant input parameters for the model based on their respective influence on the classification accuracy of the model.

The database may include the compositions of the light hydrocarbons (C1-C5 mol %) and the corresponding fluid type (oil, gas condensate, and gas). To ensure data consistency, statistical tools (e.g., Mahalanobis distance) may be advantageously used to identify and remove outliers from the database. Composition mass balance may also be checked for the samples. After such quality control, the composition may be normalized to 100% to make the data comparable to the composition measured at 102. For fluid type identification, C1-C5 mol % may be utilized as inputs (predictors) to the classification model.

The fluid classification model 104 may advantageously the make use of various predictors including the wetness Wh, balance Bh, and character Ch of the gas sample as defined below:

$$Wh = \frac{C 2 + C 3 + C 4 + C 5}{C 1 + C 2 + C 3 + C 4 + C 5}$$

$$Bh = \frac{C 1 + C 2}{C 3 + C 4 + C 5}$$

$$Ch = \frac{C 4 + C 5}{C 3}$$

where C1, C2, C3, C4, and C5 represent the mol % or proportion of each of the light alkane gases in the measurements made at 102. In such embodiments, the training may establish correlations between one or more of the predictors and the corresponding fluid type.

In example embodiments, for generating and training the fluid type classification model, a Random Forest (RF) algorithm may be selected as the classification model. RF is a supervised learning model, a subclass of rule-based decision tree algorithm. Given a training dataset with input parameters and target classes, the decision tree algorithm may generate a set of rules that may then be used to predict the classes using the parameters from a new dataset. In RF, the model randomly selects predictors from the available input parameters to build decision trees and combines many decision trees into a single model. The model calculates the votes for each predicted target class and consider the class with the highest vote as the final prediction. However, other classification models, alone or in combination, may be chosen.

The samples in the preexisting database may be split for training and validation purposes. For example, 80% of the samples (randomly selected) may be utilized as a training set, and the remaining (20%) of the samples may be utilized for validation. However, other proportions may also be utilized within the scope of the present disclosure. The fluid type classification model may be trained using, for example, a cross-validation technique. The RF parameters (number of trees, etc.) may be optimized for improved performance with Bayesian Optimization (BO), grid search, random search, or stochastic gradient search. Generally, large ranges may be defined for each of the parameters to be optimized, then the algorithm may iteratively determine for the best combination of parameters that minimizes cross-validation error of the training data.

An example embodiments, the workflow for training and implementing the model may use a hierarchical classification model with two sub-models to improve the accuracy of the fluid-type classification (see FIG. 4). The first sub-model may identify the fluid as an “Oil” type or a “Gas Condensate/Gas” type. The samples identified as “Gas Condensate/Gas” may then be classified as “Gas Condensate” or “Gas” type using the second sub-model.

The it will be appreciated that the disclosed embodiments are not limited to the three fluid types described above. For example, the classification model (or models) may be extended to include other classes or subclasses of the three classes described above, such as light oil, medium oil, heavy oil, volatile oil, etc. Moreover, the disclosed embodiments are not limited to merely using the gas measurements received at 102. Rather, the disclosed embodiments may also permit the use of other measurements, for example, including various logging while drilling measurements. In certain embodiments these other measurements may improve classification capability when the preexisting database includes such other measurements.

With continued reference to FIG. 3, the reservoir fluid may be further classified as normal or abnormal at 106. In example embodiments, the reservoir fluid may be classified as abnormal at 106 when it shows signs of having undergone a biodegradation process and normal when it does not show such signs of having undergone biodegradation (or only shows minimal signs thereof). In other example embodiments, the reservoir fluid may be classified as abnormal at 106 for other reasons, such as geological processes including fractionation, mixing, secondary processes, etc., temperature and pressure conditions, and variations in the source material. It may be advantageous to distinguish between normal and abnormal reservoir fluids since such altered fluids may have a particular composition that can deteriorate C6+ and GOR predictions. In example embodiments the second machine learning model may include a Random Forest model.

The second machine learning model (used to classify the reservoir fluid as normal or abnormal at 106) may be trained, for example, as described above using a database including the compositions of the light hydrocarbons (C1-C5 mol % or C1-C6+ mole %), the fluid type, and the corresponding normal or abnormal classification for a large number of gas samples. The second machine learning model may be advantageously trained to identify relationships between C1-C5 and C6 or C6+ and to thereby classify the reservoir fluid as normal or abnormal. The second machine learning model may further make use of a number of predictors or markers of fluid abnormality. For example, markers of biodegradation may include one or more ratios of iso-butane to n-butane (iC4/nC4) and iso-pentane to n-pentane (iC5/nC5), or a ratio of ethane to propane (C2/C3) in the gas composition measurements received at 102. In such embodiments, the model training may establish correlations between one or more of these markers and/or relationships and normal or abnormal fluids.

As further depicted in FIG. 3, third and fourth machine learning models may be used to predict the C6+ fraction of the reservoir fluid. In particular, the third model being used when the reservoir fluid is classified as normal and the fourth model being used when the reservoir fluid is classified as abnormal. The third and fourth machine learning models (used to predict the C6+ fraction) may include statistical, or regression, models, such as Gaussian Process Regression (GPR) models. As described above, a database may be used to train and optimize the statistical (regression) models. These statistical models may be developed to predict the C6+ fraction for each classification (normal or abnormal). The trained third and fourth machine learning models may be configured to predict the C6+ fraction from the gas composition measurements made at 102 and the fluid classification estimate made at 104.

Moreover, it will be noted that each of the second classification model and the third and fourth prediction (or regression) models receive as input both the gas measurements made at 102 and the fluid classification estimate made at 104. It has been found that use of the fluid classification estimate tends to improve the predictive capability of the second machine learning model and therefore may provide a more accurate classification of normal and abnormal fluids as well as a more accurate C6+ prediction. While not wishing to be bound by theory, it is believed that the fluid classification estimate advantageously provides additional information about the underlying structure of the measurements made at 102, which enables the second, third, and fourth machine learning models to capture more complex relationships between the continuous features in the measurements and the fluid type. Moreover, the model tends to be able to learn to differentiate between different groups of observations, which helps to avoid overfitting the data when training the model (as the model can better generalize to new data by considering the variability existing among the types).

Moreover, in example embodiments third and fourth machine learning models may estimate the C6+ fraction, according to a “location” of the composition in a multi-dimensional space of composition parameters (e.g., C1, C2, C3, C4, C5, Wh, Bh, Ch, etc.). For example, the set of composition parameters may be assembled and the model may be configured to correlate these parameters with the C6+ fraction. These parameters may be correlated with the C6+ fraction such that in practice the model assigns a C6+ fraction based on the set of values of those parameters (or stated another way based on the location of the fluid in the aforementioned multi-dimensional parameter space). It will be appreciated that the third and fourth models may make use of the same set of composition parameters. In such embodiments, the particular location of the fluid in the multi-dimensional parameter space may map to a first C6+ fraction in the third model (for a normal fluid) and to a second, different C6+ fraction in the fourth model (for an abnormal fluid). Stated another way, the third model may include a first correlation between the multi-dimensional feature space and the C6+ fraction and the fourth model may include a second different correlation between the multi-dimensional feature space and the C6+ fraction.

With still further reference to FIG. 3, the gas measurements received at 102, the estimated fluid type classified at 104, and the C6+ fraction predicted at 110 or 112 may be further evaluated at 114 using a fifth machine learning model to predict GOR of the reservoir fluid. The fifth machine learning models (used to predict the GOR) may include statistical, or regression, models, such as a GPR model. As described above, a database may be used to train and optimize the statistical (regression) models to predict the GOR from the gas composition measurements made at 102, the fluid classification estimate made at 104, and the C6+ estimate made at 110 or 112.

Noted that the fifth machine learning model receives as input the gas measurements made at 102, the fluid classification estimate made at 104, and the C6+ prediction made at 110 or 112. It has been found that use of the fluid classification and the C6+ prediction tends to improve the predictive capability of the fifth machine learning model and therefore may provide a more accurate prediction of the gas oil ratio. While not wishing to be bound by theory, and as described above, it is believed that the fluid classification estimate advantageously provides additional information about the underlying structure of the gas measurements made and may help avoid overfitting the data during training.

Turning now to FIG. 4, method 150 includes receiving a gas composition measurements at 152. As described above, the gas measurement may include C1, C2, C3, C4, and C5 measurements made, for example, using the FlairFlex service as described above. The gas measurements received that 152 may be evaluated using a set of Random Forest machine learning fluid classification models at 154 and 160 to estimate a reservoir fluid type. In the depicted embodiment, a first Random Forest model 154 may be configured to evaluate the received gas measurements to group (or classify) the fluid as either an oil 156 or as a subgroup 158 containing either gas condensate or gas. The received gas measurements may then be further evaluated using a second Random Forest model 160 to classify the reservoir fluid (and the subgroup 158) as either a gas condensate 162 or a gas 164. In this way, the reservoir fluid may be classified as an oil, a gas, or a gas condensate at 166.

With continued reference to FIG. 4, a third Random Forest machine learning model 170 may be used to classify the reservoir fluid as normal 172 or abnormal 174 based on the gas measurements received at 152 and the estimated fluid type classification at 166. The third Random Forest machine learning model may be configured to make use of various markers and/or predictors that may indicate evidence of biodegradation or fluid mixing as described above with respect to FIG. 3. First and second Gaussian Process Regression models 182 and 184 may be configured to predict the C6+ fraction 186 and 188 of the reservoir fluid for the normal and abnormal reservoir fluids based on the gas measurements received at 152 and the estimated fluid type classification at 166. The first GPR model may be used at 182 when the fluid is classified as normal 172 and the second GPR model may be used at 184 when the fluid is classified as abnormal at 174. A third GPR model 192 may be configured to predict the gas oil ratio 194 of the reservoir fluid from the gas measurements received at 152, the estimated fluid type classified at 166, and the C6+ fraction predicted at 190. The process may then be repeated substantially any number of times based on successive gas composition measurements.

With continued reference to FIGS. 3 and 4, the predictions of C6+ fraction and GOR may advantageously use as input the gas measurements including the C1-C5 components as well as one or more features extracted using K-means. By extracted features it is meant that the cluster assignments of the data points generated by the unsupervised K-means clustering algorithm are used as new features or variables. Using cluster assignments as features can sometimes be useful, especially when the original features have complex relationships that are not linearly separable. K-means clustering can help identify underlying patterns in the data and create new features that capture these patterns.

The addition of K-means generated features to a pre-trained model advantageously transfers knowledge of the underlying structure of the data from one database to another. This may help the pre-trained model to better generalize the new database and capture patterns and correlations that may not be present in the original data. Moreover, K-means may be readily retrained with new data to establish new relationships and to extract new features. Retraining the K-means model with new data may allow a better fit to the underlying structure of the current data, which may lead to more accurate and relevant feature extraction that benefits the regression model in predicting the new data. The addition of K-means generated features can act as a form of regularization, helping to avoid over-fitting the pre-trained model to the original data. Furthermore, these additional features may improve model performance by providing a richer and more complete representation of the data.

In one example embodiment of method 150, the Random Forest fluid classification sub-models make use of C1-C5 input data as well as the wetness Wh and balance Bh predictors. The Random Forest normal/abnormal classification model may make use of C1-C5 input data as well one or more of the above described biodegradation markers. The Gaussian Process Regression models used to predict the C6+ fraction and the GOR may make use of C1-C5 input data as well as the wetness Wh and balance Bh predictors and at least one K-means feature.

As described above, the disclosed embodiments make use of multiple machine learning models, for example, including five distinct machine learning models. As also described above these models may be trained using a database including several thousand samples. In advantageous embodiments the models may also be retrained with a subsequent database including samples that are pertinent to specific basins. By retraining the machine learning models to align with the unique characteristics of each basin, the accuracy and the applicability of the model output to the specific basin may be significantly enhanced. The model's accuracy and applicability to that specific context.

It will be understood that the present disclosure includes numerous embodiments. These embodiments include, but are not limited to, the following embodiments.

In a first embodiment, method for predicting properties of a reservoir fluid during a mud logging operation, the method comprising: obtaining a measured composition of a gas sample obtained during a mud logging operation, the measured composition including selected alkane gases; classifying a fluid type of the reservoir fluid from the measured composition with a first trained machine learning model; classifying the reservoir fluid as normal or abnormal from the measured composition and the classified fluid type with a second trained machine learning model; predicting a heavy hydrocarbon fraction of the reservoir fluid when the reservoir fluid is classified as normal from the measured composition and the classified fluid type with a third trained machine learning; predicting a heavy hydrocarbon fraction of the reservoir fluid when the reservoir fluid is classified as abnormal from the measured composition and the classified fluid type with a fourth trained machine learning model; and predicting a gas oil ratio of the reservoir fluid from the measured composition, the classified fluid type, and the predicted heavy hydrocarbon fraction with a fifth trained machine learning model.

A second embodiment may include the first embodiment, further comprising outputting the classified fluid type, the predicted heavy hydrocarbon fraction, and the predicted gas oil ratio to a mud log.

A third embodiment may include any one of the first through second embodiments, wherein the obtaining further comprises: circulating drilling fluid in a wellbore while drilling; degassing a portion of the drilling fluid to obtain the gas sample; and making gas chromatography measurements on the gas sample to obtain the measured composition of the gas sample.

A fourth embodiment may include any one of the first through third embodiments, wherein: the first and second trained machine learning models comprise first and second Random Forest classification models; and the third, fourth, and fifth trained machine learning models comprise first, second, and third Gaussian Process Regression models.

A fifth embodiment may include any one of the first through fourth embodiments, wherein the classified fluid type consists of oil, gas condensate, or gas.

A sixth embodiment may include any one of the first through fifth embodiments, wherein the first trained machine learning model further comprises: a first sub-model configured to classify the fluid type as a first type of reservoir fluid and a group including at least a second type of reservoir fluid and a third type of reservoir fluid; and a second sub-model configured to classify the group as either the second type of reservoir fluid or the third type of reservoir fluid.

A seventh embodiment may include any one of the first through sixth embodiments, wherein the classifying the reservoir fluid as normal or abnormal further comprises evaluating at least one biodegradation marker with the second trained machine learning model.

An eighth embodiment may include any one of the first through seventh embodiments, wherein: the third machine learning model maps a multi-dimensional gas composition feature space to a first heavy hydrocarbon fraction of the reservoir when the reservoir fluid is classified as normal; and the fourth machine learning model maps the multi-dimensional gas composition feature space to a second, different heavy hydrocarbon fraction of the reservoir when the reservoir fluid is classified as abnormal.

A ninth embodiment may include any one of the first through eighth embodiments, wherein the third machine learning model, the fourth machine learning model, and the fifth machine learning model are further configured to evaluate at least one K-means extracted feature.

A tenth embodiment may include any one of the first through ninth embodiments, wherein: the first machine learning model and the second machine learning model are configured to further evaluate at least one of a wetness Wh, a balance Bh, and a character Ch of the gas sample; and the second machine learning model, the third machine learning model, and the fourth machine learning model are configured to evaluate at least one of a wetness Wh, a balance Bh, and a character Ch of the gas sample and at least one K-means extracted feature.

In an eleventh embodiment a system for predicting properties of a reservoir fluid during a mud logging operation comprises, a processing system comprising a processor and memory storing program code instructions executable by the processor to: obtain a measured composition of a gas sample obtained during a mud logging operation, the measured composition including selected alkane gases; classify a fluid type of the reservoir fluid from the measured composition with a first trained machine learning model; classify the reservoir fluid as normal or abnormal from the measured composition and the classified fluid type with a second trained machine learning model; predict a heavy hydrocarbon fraction of the reservoir fluid when the reservoir fluid is classified as normal from the measured composition and the classified fluid type with a third trained machine learning; predict a heavy hydrocarbon fraction of the reservoir fluid when the reservoir fluid is classified as abnormal from the measured composition and the classified fluid type with a fourth trained machine learning model; and predict a gas oil ratio of the reservoir fluid from the measured composition, the classified fluid type, and the predicted heavy hydrocarbon fraction with a fifth trained machine learning model.

A twelfth embodiment may include the eleventh embodiment, further comprising: a degasser configured to extract the gas sample from circulating drilling fluid during the mud logging operation; and a gas chromatography apparatus configured to measure the measured composition of the gas sample.

A thirteenth embodiment may include any one of the eleventh through twelfth embodiments, wherein: the first and second trained machine learning models comprise first and second Random Forest classification models; and the third, fourth, and fifth trained machine learning models comprise first, second, and third Gaussian Process Regression models.

A fourteenth embodiment may include any one of the eleventh through thirteenth embodiments, wherein the list second trained machine learning model is configured to evaluate at least one biodegradation marker in classifying the reservoir fluid as normal or abnormal.

A fifteenth embodiment may include any one of the eleventh through fourteenth embodiments, wherein: the first machine learning model and the second machine learning model are configured to further evaluate at least one of a wetness Wh, a balance Bh, and a character Ch of the gas sample; and the second machine learning model, the third machine learning model, and the fourth machine learning model are configured to evaluate at least one of a wetness Wh, a balance Bh, and a character Ch of the gas sample and at least one K-means extracted feature.

In a sixteenth embodiment, a method for predicting properties of a reservoir fluid during a mud logging operation, the method comprising: obtaining a measured composition of a gas sample obtained during a mud logging operation, the measured composition including selected alkane gases; classifying the reservoir fluid as normal or abnormal from the measured composition and a classified fluid type with a trained machine learning classification model; predicting a heavy hydrocarbon fraction of the reservoir fluid when the reservoir fluid is classified as normal from the measured composition and the classified fluid type with a first trained machine learning regression model; and predicting a heavy hydrocarbon fraction of the reservoir fluid when the reservoir fluid is classified as abnormal from the measured composition and the classified fluid type with a second trained machine learning regression model.

A seventeenth embodiment may include the sixteenth embodiment, wherein the classifying the reservoir fluid as normal or abnormal further comprises evaluating at least one biodegradation marker with the second trained machine learning model.

An eighteenth embodiment may include any one of the sixteenth through seventeenth embodiments, wherein: the first trained machine learning regression model maps a multi-dimensional gas composition feature space to a first heavy hydrocarbon fraction of the reservoir when the reservoir fluid is classified as normal; and the second trained machine learning regression model maps the multi-dimensional gas composition feature space to a second, different heavy hydrocarbon fraction of the reservoir when the reservoir fluid is classified as abnormal.

A nineteenth embodiment may include any one of the sixteenth through eighteenth embodiments further comprising: predicting a gas oil ratio of the reservoir fluid from the measured composition, the classified fluid type, and the predicted heavy hydrocarbon fraction with a third trained machine learning regression model.

A twentieth embodiment may include the nineteenth embodiment, wherein: the first trained machine learning regression model, the second trained machine learning regression model, and the third trained machine learning regression model are configured to evaluate at least one of a wetness Wh, a balance Bh, and a character Ch of the gas sample and at least one K-means extracted feature.

Although methods for machine learning estimation of reservoir fluid properties have been described in detail, it should be understood that various changes, substitutions and alternations can be made herein without departing from the spirit and scope of the disclosure as defined by the appended claims.

What is claimed is:

1. A method for predicting properties of a reservoir fluid during a mud logging operation, the method comprising:
obtaining a measured composition of a gas sample obtained during a mud logging operation, the measured composition including selected alkane gases;
classifying a fluid type of the reservoir fluid from the measured composition with a first trained machine learning model;
classifying the reservoir fluid as normal or abnormal from the measured composition and the classified fluid type with a second trained machine learning model;
predicting a heavy hydrocarbon fraction of the reservoir fluid when the reservoir fluid is classified as normal from the measured composition and the classified fluid type with a third trained machine learning;
predicting a heavy hydrocarbon fraction of the reservoir fluid when the reservoir fluid is classified as abnormal from the measured composition and the classified fluid type with a fourth trained machine learning model; and
predicting a gas oil ratio of the reservoir fluid from the measured composition, the classified fluid type, and the predicted heavy hydrocarbon fraction with a fifth trained machine learning model.

2. The method of claim 1, further comprising outputting the classified fluid type, the predicted heavy hydrocarbon fraction, and the predicted gas oil ratio to a mud log.

3. The method of claim 1, wherein the obtaining further comprises:
circulating drilling fluid in a wellbore while drilling;
degassing a portion of the drilling fluid to obtain the gas sample; and
making gas chromatography measurements on the gas sample to obtain the measured composition of the gas sample.

4. The method of claim 1, wherein:
the first and second trained machine learning models comprise first and second Random Forest classification models; and
the third, fourth, and fifth trained machine learning models comprise first, second, and third Gaussian Process Regression models.

5. The method of claim 1, wherein the classified fluid type consists of oil, gas condensate, or gas.

6. The method of claim 1, wherein the first trained machine learning model further comprises:
a first sub-model configured to classify the fluid type as a first type of reservoir fluid and a group including at least a second type of reservoir fluid and a third type of reservoir fluid; and
a second sub-model configured to classify the group as either the second type of reservoir fluid or the third type of reservoir fluid.

7. The method of claim 1, wherein the classifying the reservoir fluid as normal or abnormal further comprises evaluating at least one biodegradation marker with the second trained machine learning model.

8. The method of claim 1, wherein:
the third machine learning model maps a multi-dimensional gas composition feature space to a first heavy hydrocarbon fraction of the reservoir when the reservoir fluid is classified as normal; and
the fourth machine learning model maps the multi-dimensional gas composition feature space to a second, different heavy hydrocarbon fraction of the reservoir when the reservoir fluid is classified as abnormal.

9. The method of claim 1, wherein the third machine learning model, the fourth machine learning model, and the fifth machine learning model are further configured to evaluate at least one K-means extracted feature.

10. The method of claim 1, wherein:
the first machine learning model and the second machine learning model are configured to further evaluate at least one of a wetness Wh, a balance Bh, and a character Ch of the gas sample; and
the second machine learning model, the third machine learning model, and the fourth machine learning model are configured to evaluate at least one of a wetness Wh, a balance Bh, and a character Ch of the gas sample and at least one K-means extracted feature.

11. A system for predicting properties of a reservoir fluid during a mud logging operation, the system comprising:
a processing system comprising a processor and memory storing program code instructions executable by the processor to:
obtain a measured composition of a gas sample obtained during a mud logging operation, the measured composition including selected alkane gases;
classify a fluid type of the reservoir fluid from the measured composition with a first trained machine learning model;
classify the reservoir fluid as normal or abnormal from the measured composition and the classified fluid type with a second trained machine learning model;
predict a heavy hydrocarbon fraction of the reservoir fluid when the reservoir fluid is classified as normal from the measured composition and the classified fluid type with a third trained machine learning;
predict a heavy hydrocarbon fraction of the reservoir fluid when the reservoir fluid is classified as abnormal from the measured composition and the classified fluid type with a fourth trained machine learning model; and
predict a gas oil ratio of the reservoir fluid from the measured composition, the classified fluid type, and the predicted heavy hydrocarbon fraction with a fifth trained machine learning model.

12. The system of claim 11, further comprising:
a degasser configured to extract the gas sample from circulating drilling fluid during the mud logging operation; and
a gas chromatography apparatus configured to measure the measured composition of the gas sample.

13. The system of claim 11, wherein:
the first and second trained machine learning models comprise first and second Random Forest classification models; and
the third, fourth, and fifth trained machine learning models comprise first, second, and third Gaussian Process Regression models.

14. The system of claim 11, wherein the list second trained machine learning model is configured to evaluate at least one biodegradation marker in classifying the reservoir fluid as normal or abnormal.

15. The system of claim 11, wherein:
the first machine learning model and the second machine learning model are configured to further evaluate at least one of a wetness Wh, a balance Bh, and a character Ch of the gas sample; and
the second machine learning model, the third machine learning model, and the fourth machine learning model are configured to evaluate at least one of a wetness Wh, a balance Bh, and a character Ch of the gas sample and at least one K-means extracted feature.

16. A method for predicting properties of a reservoir fluid during a mud logging operation, the method comprising:
obtaining a measured composition of a gas sample obtained during a mud logging operation, the measured composition including selected alkane gases;
classifying the reservoir fluid as normal or abnormal from the measured composition and a classified fluid type with a trained machine learning classification model;
predicting a heavy hydrocarbon fraction of the reservoir fluid when the reservoir fluid is classified as normal from the measured composition and the classified fluid type with a first trained machine learning regression model; and
predicting a heavy hydrocarbon fraction of the reservoir fluid when the reservoir fluid is classified as abnormal from the measured composition and the classified fluid type with a second trained machine learning regression model.

17. The method of claim 16, wherein the classifying the reservoir fluid as normal or abnormal further comprises evaluating at least one biodegradation marker with the second trained machine learning model.

18. The method of claim 16, wherein:
the first trained machine learning regression model maps a multi-dimensional gas composition feature space to a first heavy hydrocarbon fraction of the reservoir when the reservoir fluid is classified as normal; and
the second trained machine learning regression model maps the multi-dimensional gas composition feature space to a second, different heavy hydrocarbon fraction of the reservoir when the reservoir fluid is classified as abnormal.

19. The method of claim 16, further comprising:
predicting a gas oil ratio of the reservoir fluid from the measured composition, the classified fluid type, and the predicted heavy hydrocarbon fraction with a third trained machine learning regression model.

20. The method of claim 19, wherein:
the first trained machine learning regression model, the second trained machine learning regression model, and the third trained machine learning regression model are configured to evaluate at least one of a wetness Wh, a balance Bh, and a character Ch of the gas sample and at least one K-means extracted feature.
